(19) United States
(12) Patent Application Publication
(10) Pub. No.: US 2010/0065956 A1
(43) Pub. Date: Mar. 18, 2010

(54) PACKAGING STRUCTURE, PACKAGING METHOD AND PHOTOSENSITIVE DEVICE

(76) Inventors: Zhiqi WANG, Suzhou Industrial Park (CN); Guoqing Yu, Suzhou Industrial Park (CN); Qiuhong Zou, Suzhou Industrial Park (CN); Wei Wang, Suzhou Industrial Park (CN)

Correspondence Address: FROMMER LAWRENCE & HAUG LLP, 745 FIFTH AVENUE, NEW YORK, NY, 10151, US

(21) Appl. No.: 12/412,778

(22) Filed: Mar. 27, 2009

(30) Foreign Application Priority Data
Sep. 12, 2008 (CN) 200810042930.8

(51) Int. Cl. H01L 23/485; H01L 21/50

(52) U.S. Cl. 257/690; 438/118; 257/737; 257/E21.499; 257/E23.021

(57) ABSTRACT

The application provides a packaging structure, a packaging method and a photosensitive device. The packaging structure includes a substrate structure, a chip and a solder bump electrically connecting with a pad on the chip. The solder bump is located on the substrate structure, so that the multilayer coverage structure required when forming a bump on a side of the chip in the prior art packaging structure is avoided. In this way, the thickness of the packaging structure is reduced and the reliably of the packaging structure is improved.

### CROSS REFERENCES OF RELATED APPLICATION

The application claims priority from the Chinese patent application No. 200810042930.8 filed on Sep. 12, 2008 and entitled “PACKAGING STRUCTURE, PACKAGING METHOD AND PHOTOSENSITIVE DEVICE”, the contents of which are incorporated herein by reference in its entirety.

### FIELD OF THE INVENTION

The application relates to a packaging structure, a packaging method for forming the packaging structure and a photosensitive device having such a packaging structure.

### BACKGROUND OF THE INVENTION

Wafer Level Chip Size Packaging (WLCSP) technology is a technology in which a whole wafer is packaged and tested before being diced into individual chips. Such a technology is totally different from the conventional packaging technologies, such as Chip On Board (COB), where a whole wafer is thinned and diced into individual chips and then the chips are wire bonded. The size of a chip after being packaged with the WLCSP technology is almost the same as that of a bare chip. The WLCSP technology satisfies the requirements for the microelectronic products, such as light weight, small size (especially in length and thickness) and low cost. A chip packaged with the WLCSP technology realizes its miniaturization, and the cost of the chip is reduced significantly with the decrease in chip size and the increase in wafer size. The WLCSP technology, as a technology that takes into account the IC design, wafer fabrication, packaging test and substrate fabrication as a combination, is a focus in the packaging field and represents a trend of the packaging technologies.

US patent application No. US2001018236, which is assigned to Shellcase Ltd., discloses a packaging structure and a method for forming the packaging structure that are based on the WLCSP technology. As shown in FIG. 1, the disclosed packaging structure includes a substrate 114, a cavity wall 116 on the substrate 114, pads 112, a chip 102 including a photosensitive element 101, and bumps 110. The cavity wall 116 on the substrate 114 is sealed, via the pads 112, over a first surface of the chip 102 to define a cavity 120. An epoxy layer 104 is formed over the other surface of the chip 102, and the other surface of the epoxy layer 104 is covered by a glass layer 106, along the edge of which an intermediate metal layer 108 is formed. The intermediate metal layer 108 is electrically connected to the pads 112 and the bumps 110.

As can be seen, in the packaging structure as shown in FIG. 1, multiple layers are required to cover over a side of the chip 102 that is opposite to the other side having the photosensitive element 101 thereon, so as to provide the functions of support and insulation, etc. Accordingly, the thickness of the packaging structure 100 is increased. In addition, the pads 112 and the intermediate metal layer 108 are prone to disconnect from each other because of the small contacting area therebetween.

FIG. 2 shows a schematic diagram illustrating the assembling of the above packaging structure. After the assembling, the total thickness of the packaging structure 100 is equal to the sum of half of the thickness of a lens 170, the focus length of the lens 170, the distance between the photosensitive element 101 and the bumps 110, and the thickness of a Printed Circuit Board (PCB)160. Also from FIG. 2, the diameter of the lens 170 is typically longer than the diagonal of the square substrate 114 in the packaging structure 100 so as to facilitate the assembling of the packaging structure 100.

As shown in FIG. 2, the existing packaging structure 100 is thick and the size of the lens 170 is large. Moreover, in the existing structures, extension pads (not shown), besides the pads 112, may be required on the chip 102. In such cases, the available area of the wafer for making the chip 102 is further reduced.

### SUMMARY OF THE INVENTION

A problem to be solved by the application is how to improve the reliability of the packaging structure while decreasing the thickness of the packaging structure.

According to one aspect of the application, there is provided a packaging structure which includes a substrate, a chip, a solder bump electrically connected to a pad located on the chip. The solder bump is provided on the substrate.

According to another aspect of the application, there is provided a packaging method which includes the steps of: providing a half-finished packaging structure including a substrate and a chip on which an exposed pad is provided; forming a solder bump on a side of the substrate in the half-finished packaging structure, the solder bump being electrically connected with the pad.

According to yet another aspect of the application, there is provided a photosensitive device which includes a packaging structure, a lens and a Printed Circuit Board (PCB). The PCB is located between the lens and the packaging structure.

In the packaging structure according to some embodiments of the application, the solder bump is formed on the substrate instead of being formed on a side of the chip in the packaging structure, thereby avoiding the multilayer coverage structure required to form bumps on a side of the chip in the prior art. Accordingly, the thickness of the packaging structure is reduced.

Moreover, the pad is wholly or partly covered by a conductive layer such that the contacting area between the conductive layer and the pad is increased. In this way, the possibility of occurrence of connection failure between the conductive layer and the pad is decreased and the reliability of the packaging structure is increased.

### BRIEF DESCRIPTION OF THE DRAWINGS

FIG. 1 is a schematic diagram illustrating a packaging structure in the prior art;

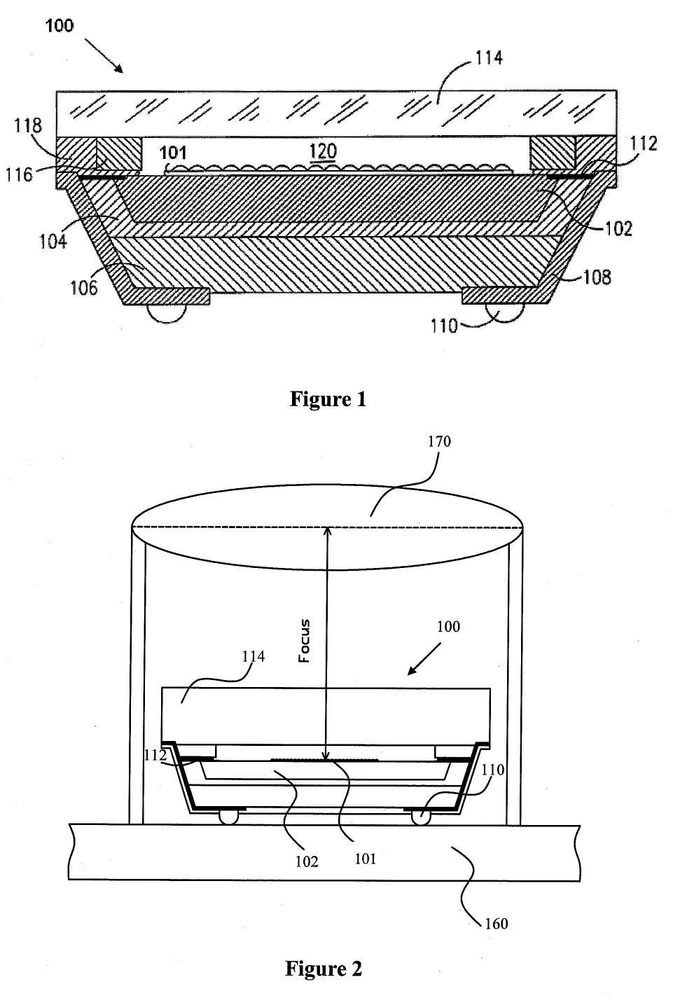

FIG. 2 is a schematic diagram illustrating the assembling of the packaging structure as shown in FIG. 1;

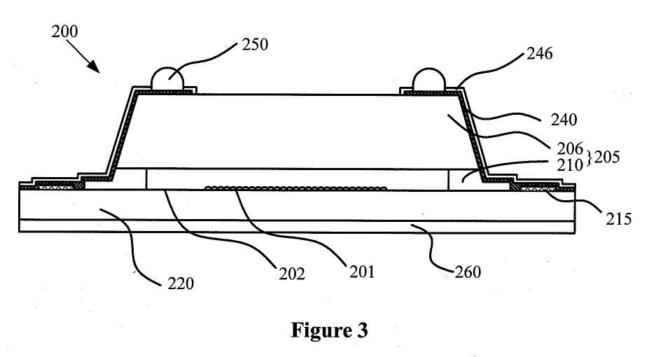

FIG. 3 is a schematic diagram illustrating the structure of a packaging structure according to an embodiment of the application;

FIG. 4 is a flow chart illustrating a packaging method according to an embodiment of the application;

FIG. 5-11 are schematic diagrams illustrating the fabrication of a packaging structure by using a packaging method according to an embodiment of the application; and

FIG. 12 is a schematic diagram illustrating the assembling of a packaging structure according to an embodiment of the application.

### DETAILED DESCRIPTION OF THE EMBODIMENTS

Embodiments of the application provide a packaging structure and a packaging method, by which the multilayer coverage structure required to from bumps on a side of a chip in a packaging structure may be avoided and thus the thickness of the packaging structure may be reduced significantly.

Some embodiments of the application will be described below with reference to the accompany drawings, taking the packaging of an optical sensor chip as an example.

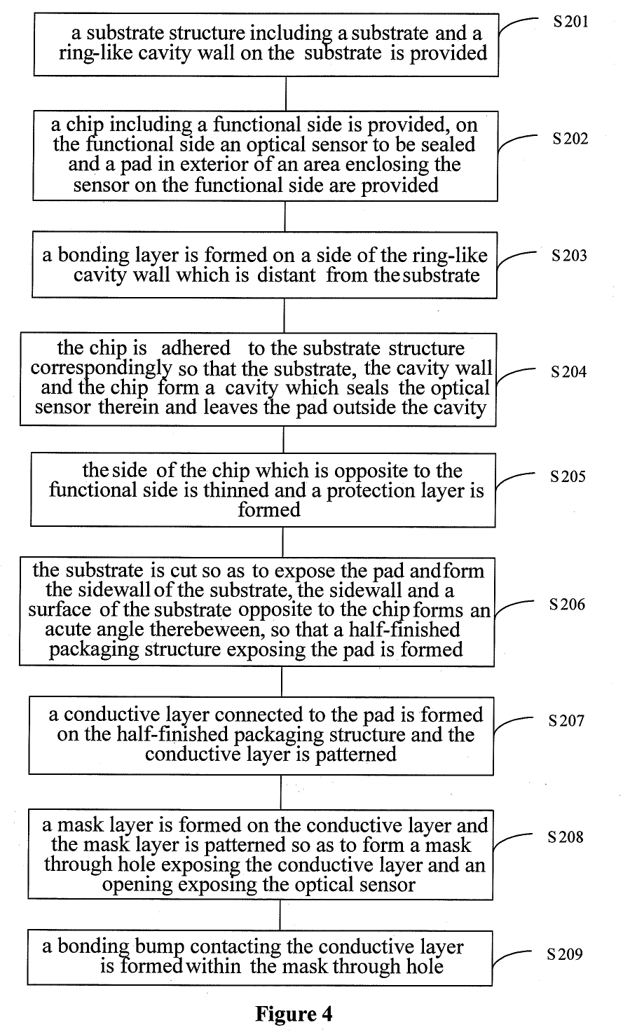

FIG. 3 illustrates a packaging structure according to an embodiment of the application. As shown in FIG. 3, the packaging structure 200 includes a substrate structure 205, a chip 220 bonded to the substrate structure 205, and solder bumps 250 provided on the substrate structure 205. In order to facilitate the solder bumps 250 to contact the PCB during the assembly of the packaging structure 200 and other devices and in order to prevent the solder bumps 250 from disengaging, the solder bumps 250 are provided on a side of the substrate structure 105 that is distant from the chip 220. Optionally, as can be appreciated by those skilled in the art, the solder bumps 250 may also be located on the sidewall of the substrate structure 250 when necessary.

The chip 220 has a functional side 202. An optical sensor 201 which needs to be sealed and pads 215 located in the exterior of the area enclosing the optical sensor 201 are provided on the functional side 202. The pads 215 connect the internal circuit of the optical sensor 201 with circuits outside the optical sensor 201. In order to reduce the thickness of the packaging structure 200, the side of the chip 220 which is opposite to the functional side 202 may be thinned by a chemical or mechanism thinning process. The thinning process may use the processes well known in the art, which are not repeated herein. The side of the chip 220 which is opposite to the functional side 202 may be coated with only a protection layer 260 for the protection of the chip. The protection layer 260 may be formed by a composite comprising BCB(Benzo-Cyclo-Butene),polyimide and epoxy. In the packaging structure 200, the solder bumps 250 are not required to be provided on a side of the chip 220, and accordingly it is not necessary to provide a multilayer coverage structure, for support, insulation and protection, on the side which is opposite to the functional side of the chip 220. This is different from the prior art. In this way, the thickness of the packaging structure 200 may be reduced.

The substrate structure 205 includes a substrate 206 and a cavity wall 210. The cavity wall 210 is located on a side of the substrate 206 facing the optical sensor 201. The cavity wall 210 is formed in a wall-like closed-ring structure and is configured to correspond to the optical sensor 201 on the chip 220. The area surrounded by the cavity wall 210 covers the optical sensor 201, but excludes the pads 215. The cavity wall 210 may be made of epoxy.

The substrate 206 on the substrate structure 205, the cavity wall 210 and the chip 220 formed a cavity there between. The optical sensor 201 is sealed in the cavity, while the pads 215 are outside the cavity.

The packaging structure 200 may also include a conductive layer 240, an end of which totally covers the pads 215. In the embodiment of the application, the conductive layer 240 contacts the pads 215 by totally covering the pads 215, which is different from the point contact in the prior art. In this way, the contact between the conductive layer 240 and the pads 215 is more stable and therefore the reliably of the packaging structure 200 is improved. Optionally, those skilled in the art can appreciate that even if the pads 215 are partly covered by the conductive layer 240 instead of being totally covered, the reliably of the contact between the conductive layer 240 and the pads 215, and thus the reliably of the packaging structure, may be improved. The other end of the conductive layer 240 directly contacts the bottom of the solder bumps 250 so that the solder bumps 250 are connected to the pads 215. In this way, electrical paths from the solder bumps 250 to the pads 215 are formed.

In order to protect the conductive layer 240, a mask layer 246 may be formed on the conductive layer 240 such that the mask layer 246 totally cover the conductive layer 240 and the pads 215. Through holes may be configured at the locations where the conductive layer 240 and the solder bumps 250 contact with each other. The diameters of the through holes may be equal or approximately equal to the radial diameters of the solder bumps 250 so that the mask layer 246 can totally cover the conductive layer 240 while exposing the solder bumps 250. The mask layer 246 may be made of thermoplastic photosensitive resin, such as a composite of BCB(Benzo-Cyclo-Butene),polyimide, and epoxy.

In order to deposit the conductive layer 240 through one shot during the manufacturing process, the surface of the substrate 206 which is opposite to the chip 220 and the sidewall of the substrate 206 may form an acute angel there between. For example, the acute angle may be 50°, 55°, 60°, 65°, 70°, 75°, or 80°, etc.

Those skilled in the art can appreciate that the number of the solder bumps and the corresponding pads may be one or more. In an embodiment of the application, a plurality of solder bumps 250 and pads 215 may be provided in the packaging structure. In this case, the conductive layer 240 may be patterned so as to form an independent signal path between each solder bump 250 and a corresponding pad 215.

Since conductivity is the most important property of the conductive layer 240, the conductive layer 240 may be made of a metal such as aluminum, Al—Ni alloy or gold. According to the requirements of the packaging, the conductive layer 240 may optionally be made of Indium Tin Oxides (ITO) which is not only electrically conductive but also transparent.

Since the optical sensor 201, which is the target to be packaged, on the chip 220 needs to obtain optical signals through the substrate 206, it is necessary for the substrate 206 to be transparent in addition to its functions of providing insulation and support. For example, the substrate may be made of glass.

When the optical sensor is the target to be packaged while the conductive layer 240 is made of a metal which is opaque, the problem that the optical signals are shielded by the metal conductive layer should be taken into consideration. Therefore, in the case that the conductive layer 240 is a metal layer, the orthographic projections of the solder bumps 215 and the conductive layer 240 on the functional side 202 of the chip 220 are not intersected with the optical sensor 201, that is, the orthographic projections are separated with the optical sensor 201. Likewise, in the case that the mask layer 246 is made of an opaque material, an opening needs to be formed on the side of the substrate 206 which is distant from the chip 220, so that the optical signals can reach the optical sensor 201 through the opening and the transparent substrate 206.

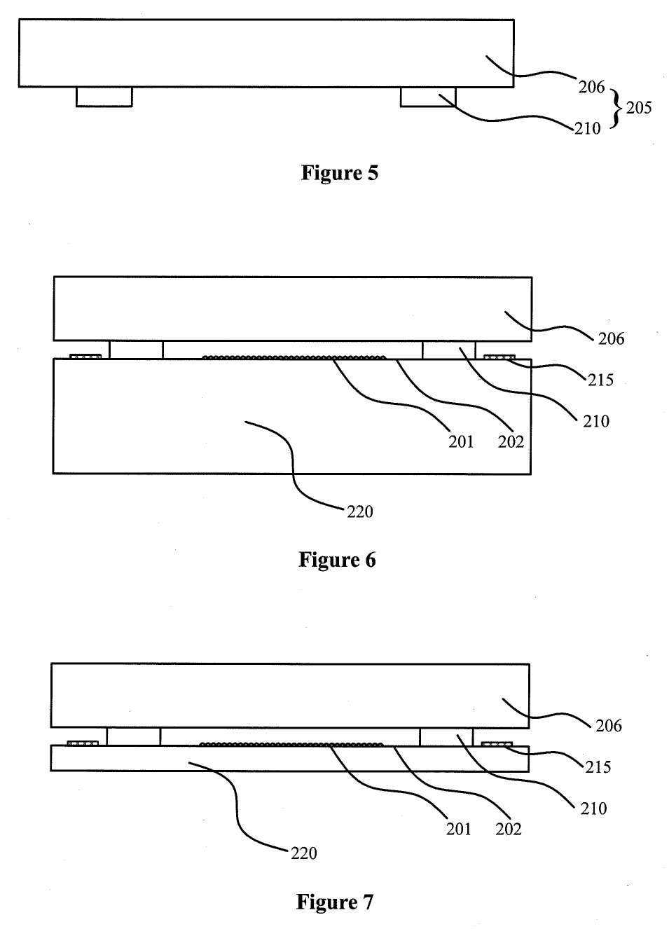

According to another aspect of the application, there is provided a method for forming the packaging structure. As shown in FIG. 4, the method according to an embodiment of the application includes the following steps.

S201. A substrate structure including a substrate and a ring-like cavity wall on the substrate is provided.

S202. A chip including a functional side is provided. On the functional side, an optical sensor which needs to be sealed and a pad located in the exterior of the area enclosing the device on the functional side are provided.

S203. An adhesive layer is formed on a side of the ring-like cavity wall which is distant from the substrate.

S204. The chip is adhered to the substrate structure correspondingly so that the substrate structure, the cavity wall and the chip form a cavity. The cavity seals the optical sensor therein but leaves the pad outside the cavity.

S205. The side of the chip which is opposite to the functional side is thinned and a protection layer is formed.

S206. The substrate is cut such that the pad is exposed and the sidewall of the substrate is formed. The angle formed between the sidewall of the substrate and the side of the substrate which is opposite to the chip is an acute angle. In this way, a half-finished packaging structure in which the pad is exposed is formed.

S207. A conductive layer connected to the pad is formed on a side of the substrate structure in the half-finished packaging structure and the conductive layer is patterned.

S208. A mask layer is formed over the conductive layer and the mask layer is patterned so as to form a mask through hole exposing the conductive layer and an opening exposing the optical sensor.

S209. A solder bump contacting the conductive layer is formed in the mask through hole.

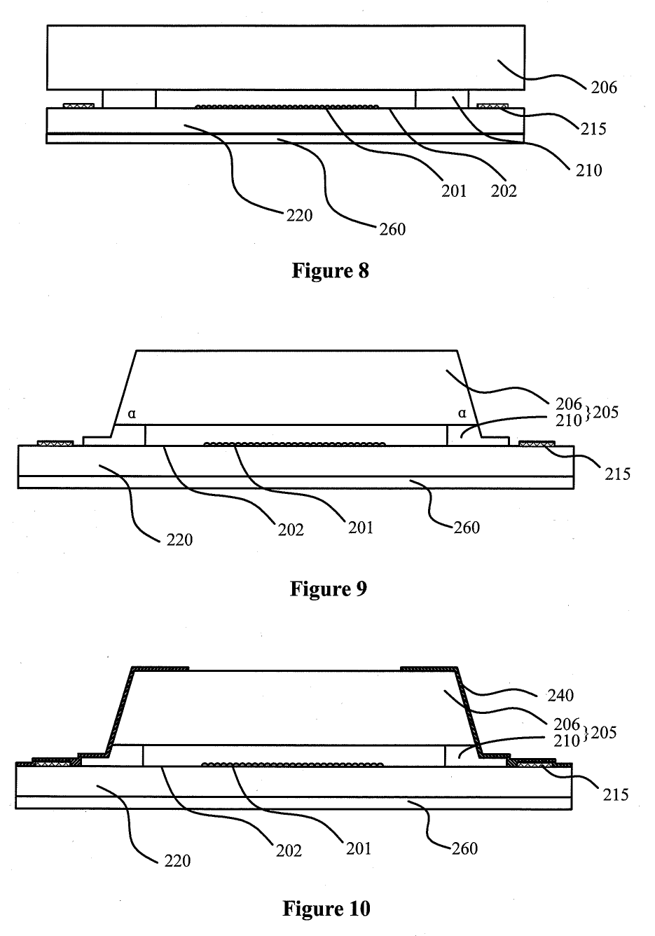

FIGS. 5-11 are schematic diagrams illustrating a procedure for manufacturing the packaging structure using a packaging method according to an embodiment of the application. The packaging method is described below with reference to FIGS. 5-11.

As shown in FIG. 5, step S201 is performed first during which the substrate structure 205 including the substrate 206 and the ring-like cavity wall 210 is provided. The structure of the substrate structure 205 is disclosed in the above description regarding the packaging structure 200 and will not be repeated herein.

Then, step S202 is performed during which the chip 220 is provided. The chip 220 includes a functional side 202. On the functional side 202, the optical sensor 201 which needs to be sealed and the pad 215 located in the exterior of the area enclosing the optical sensor 201 are provided.

Then, step S203 is performed during which the bonding layer (not shown) is formed on a side of the ring-like cavity wall which is distant from the substrate 206. The function of the bonding layer may includes bonding, insulation and sealing, etc. The bonding layer may be made of epoxy, polyimide, BCB(Benzo-Cyclo-Butene) resin or BT(B,Bismaleimide T,Triazine)resin.

Next step S204 is performed during which the chip 220 is adhered to the substrate structure 205 correspondingly so that the substrate 206, the cavity wall 210 and the chip 220 form a cavity which seals the optical sensor 201 therein but leaves the pad 215 outside the cavity. Thus, the structure as shown in FIG. 6 is formed. When being adhered, the optical sensor 201 on the chip 220 is configured to be located in the cavity formed by the cavity wall 210 on the substrate structure 205 while the pad 215 is left outside the cavity. In this way, the packaging structure in which the optical sensor is sandwiched between the chip 220 and the substrate structure 205 is formed.

Then step S205 is performed during which the side of the chip 220 which is opposite to the functional side is thinned, so that the structure as shown in FIG. 7 is formed. Then the protection layer 260 is formed on the side of the chip 220 which is opposite to the functional side 202. In this way, the structure as shown in FIG. 8 is formed. The detailed descriptions regarding the thinning process and the protection layer are provided in the above descriptions of the packaging structure 200 and will not be repeated herein.

Then the step S206 is performed during which the substrate 206 is cut such that the sidewall of the substrate 206 is formed. The angel a formed between the sidewall of the substrate and the side of the substrate 206 which is opposite to the chip 220 is an acute angle, such as 50°, 55°, 60°, 65°, 70°, 75° and 80°. In this way, the half-finished packaging structure in which the pad 215 is exposed as shown in FIG. 9 is formed. During the cutting, a portion of the cavity wall 210 may be cut off as shown in FIG. 9. Optionally, none portion of cavity wall 210 is cut off, so as to prevent the reduction in the mechanical strength of the cavity wall 210.

Then the step S207 is performed during which the conductive layer 240 totally covering the pad 215 is formed on one side of the substrate structure 205 in the half-finished packaging structure and the conductive layer 240 is patterned. Thus, the structure as shown in FIG. 10 is formed. The processes for forming and patterning the conductive layer 240 may utilize the conventional processes well known in the art and will not be repeated herein.

Then the step S208 is performed during which the mask layer 246 is formed over the conductive layer 240 and the mask layer 246 is patterned so as to form the mask through hole exposing the conductive layer 240 and the opening exposing the optical sensor 20. Thus, the structure as shown in FIG. 11 is formed.

Finally step S209 is performed during which the solder bump 250 which contacts the conductive layer 240 is formed within the mask through hole. In this way, the packaging structure 200 shown in FIG. 3 is formed.

In the above packaging structure and the packaging method according to the embodiments of the application, since the substrate structure 205 has the functions of support and insulation, it is unnecessary to form any insulation layer or support layer on a side of the substrate structure 205. Thus, the thickness of the packaging structure 200 may be reduced.

Additionally, compared with the prior art, the conductive layer 240 in the above described packaging structure and packaging method is connected directly to the pad 215. Since it is unnecessary to form any other pads on the chip 220, the available area of the wafer for making the chip 220 may be maximized and the cost may be lowered.

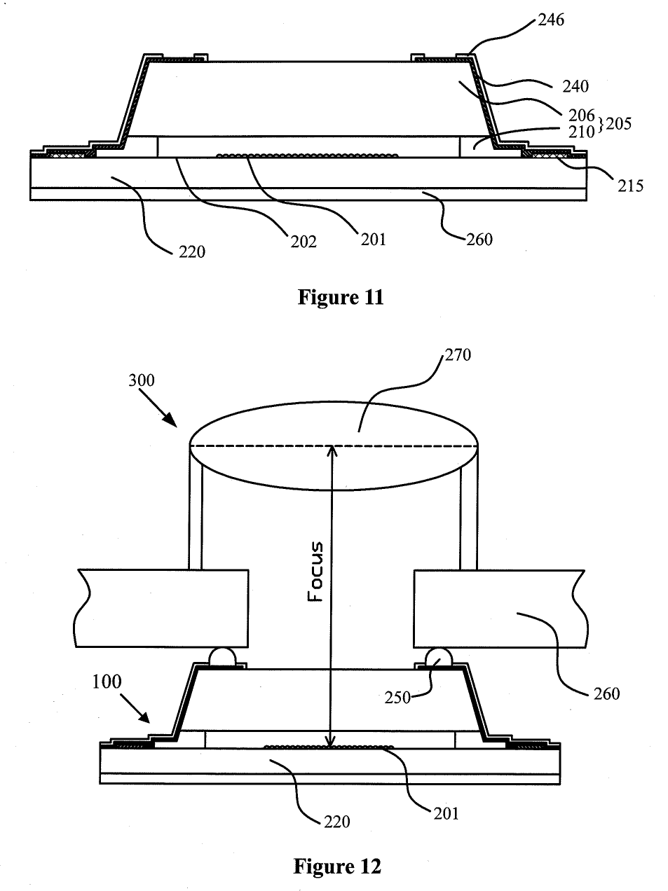

According to another aspect of the application, there is provided a photosensitive device formed by the packaging structure. As shown in FIG. 12, a photosensitive device 300 includes a packaging structure 200, a lens 270, a printed circuit board (PCB) 260. In the packaging structure 200, the solder bumps 250 are located on the substrate structure 205 and thus the PCB 260 is located between the lens 270 and the packaging structure 200. The thickness of the photosensitive device 300 is equal to the sum of half of the thickness of the lens 270, the focus length of the lens 270, and the distance between the optical sensor 201 and the protection layer 260. Compared with the prior art, at least the thickness of the PCB 260, the thickness of the solder bumps 250 and the thickness of the prior art multilayer coverage on the chip 220 are reduced, that is, the thickness of the photosensitive device 300 is reduced. Moreover, the diameter of the lens 270 may be substantially the same as that of the circum-circle of the optical sensor 201. Compared with the prior art, the size of the lens 270 is reduced significantly.

In the above embodiments, the packaging of an optical sensor is used as an example. However, the invention is not limited thereto. The packaging structure and the packaging method according to the embodiments of the application may also be applied to a semiconductor integrated circuit chip, a thermal sensor chip, a force sensor chip or a micro-electromechanical device, etc, to reduce the thickness of the packaging structure thereof.

Although the invention has been disclosed above with reference to some preferred embodiments thereof, but the invention should not be construed as limited thereto. Those skilled in the art can make any modifications and variations to the embodiments without departing from the spirit and scope of the application. Accordingly, the scope of the invention shall be defined by the following claims.

What is claimed is:

1. A packaging structure, comprising a substrate structure, a chip, and a solder bump electrically connected to a pad on the chip, wherein the solder bump is located on the substrate structure.

2. The packaging structure according to claim 1, wherein the solder bump is located on a surface of the substrate structure which is distant from the chip.

3. The packaging structure according to claim 1, further comprising a conductive layer connected to the solder bump and the pad.

4. The packaging structure according to claim 3, wherein the pad is totally or partly covered by the conductive layer.

5. The packaging structure according to claim 3, wherein the conductive layer is made of a metal or Indium Tin Oxides (ITO).

6. The packaging structure according to claim 1, further comprising a protection layer located on a side of the chip which is distant from the substrate structure.

7. The packaging structure according to claim 1, wherein a device to be sealed is configured on a functional side of the chip, the substrate structure comprises a substrate and a cavity wall, the substrate, the cavity wall and the chip form a cavity which seals the device therein and leaves the pad outside the cavity.

8. The packaging structure according to claim 7, wherein the device comprises an optical sensor and orthogonal projections of the solder bump and the conductive layer on the chip are separated from the optical sensor.

9. The packaging structure according to claim 7, wherein the substrate is made of glass.

10. The packaging structure according to claim 7, wherein an angle formed between a surface of the substrate which is opposite to the chip and a sidewall of the substrate is an acute angle.

11. A packaging method, comprising:
providing a half-finished packaging structure comprising a substrate structure and a chip having an exposed pad thereon; and forming a solder bump electrically connected with the pad on a surface of the substrate structure in the packaging structure.

12. The packaging method according to claim 11, wherein the solder bump is formed on a surface of the substrate structure which is distant from the chip.

13. The packaging method according to claim 11, wherein the pad is electrically connected to the solder bump via a conductive layer formed between the pad and the solder bump on the substrate structure.

14. The packaging method according to claim 13, wherein by totally or partly covering the pad, the conductive layer is connected to the pad.

15. The packaging method according to claim 11, further comprising: forming a protection layer on a side of the chip which is distant from the substrate structure.

16. The packaging method according to claim 11, wherein forming the half-finished packaging structure comprises:
Providing the substrate structure comprising a substrate and a ring-like cavity wall on the substrate;
Providing the chip comprising a functional side on which a device to be sealed and a pad located in exterior of an area enclosing the device on the functional side are configured;
Forming an adhesive layer on a side of the ring-like cavity wall which is distant from the substrate;
Adhering the chip to the substrate structure so that the substrate, the cavity wall and the chip form a cavity which seals the device therein and leaves the pad outside the cavity.

17. The packaging method according to claim 16, wherein the device comprises an optical sensor and orthogonal projections of the solder bump and the conductive layer on the chip are separated from the optical sensor.

18. The packaging structure according to claim 16, wherein the substrate is made of glass.

19. A photosensitive device comprising a packaging structure according to claim 1, a lens and a Printed Circuit Board (PCB), wherein the PCB is connected to a bump on the packaging structure and is located between the lens and the packaging structure.
